(19) United States
(12) Patent Application Publication
(10) Pub. No.: US 2026/0282990 A1
(43) Pub. Date: Sep. 17, 2026

(54) WIREBONDING SYSTEMS AND RELATED METHODS

(71) Applicant: SEMICONDUCTOR COMPONENTS INDUSTRIES, LLC, Scottsdale, AZ (US)

(72) Inventors: Ian Ceazar Bucayon BARIAS, Butuan City (PH); Lijuan WANG, Suzhou (CN); Sen SUN, Suzhou (CN); Jipeng HUANG, Yangzhou City (CN); ZhenYu XU, Suzhou (CN)

(73) Assignee: SEMICONDUCTOR COMPONENTS INDUSTRIES, LLC, Scottsdale, AZ (US)

(21) Appl. No.: 19/081,362

(22) Filed: Mar. 17, 2025

(51) Int. Cl. H01L 23/00

(52) U.S. Cl. CPC H10W 72/075; H10W 72/015; H10W 72/50; H10W 72/07521; H10W 72/531

(57) ABSTRACT

Implementations of a method of wirebonding may include providing a bond wire; forming a first wirebond on a surface of a substrate using a bond head and lifting the bond head away from the bond wire a predetermined distance, causing the bond wire to lift from the surface of the substrate. The method may include cutting the bond wire and forming a second wirebond on the surface of the substrate using the bond head.

### BACKGROUND

### 1. Technical Field

Aspects of this document relate generally to methods and systems for forming electrical interconnects. More specific implementations involve systems and methods for forming bond wires.

### 2. Background

Semiconductor packages have been devised that allow a semiconductor die to be protected from vibration or shock. Some semiconductor packages also contain various components that prevent the semiconductor die from being damaged by electrostatic discharge. Yet other semiconductor packages work to provide physical protection for the semiconductor die from humidity.

### SUMMARY

Implementations of a bond wire may include a wirebond attached to a substrate and a tip adjacent to the wirebond oriented at an angle pointing the tip away from a surface of the substrate.

Implementations of a bond wire may include one, all, or any of the following:

The cut face of the tip may face away from the surface.

The cut face of the tip may include a burr substantially centered in the cut face.

The angle of the tip may be over 15 degrees.

The angle of the tip may be over 25 degrees.

The angle of the tip may be over 30 degrees.

Implementations of a method of wirebonding may include providing a bond wire; forming a first wirebond on a surface of a substrate using a bond head and lifting the bond head away from the bond wire a predetermined distance, causing the bond wire to lift from the surface of the substrate. The method may include cutting the bond wire and forming a second wirebond on the surface of the substrate using the bond head.

Implementations of a method of wirebonding may include one, all, or any of the following:

The method may include forming a tip adjacent to the first wirebond and orienting the tip at an angle away from a surface of the substrate through the forming of the second wirebond.

The angle of the tip may be over 15 degrees.

The angle of the tip may be over 25 degrees.

The angle of the tip may be over 30 degrees.

The method may include forming a tip adjacent to the first wirebond and where the cut face of the tip faces away from the surface.

The method may include forming a burr in a cut face of the tip substantially centered in the cut face.

The method may include forming a burr at an angle to a cut face of the tip.

The predetermined distance may be 1.3 times a diameter of the bond wire.

Lifting the bond head away from the bond wire a predetermined distance may occur before cutting the bond wire.

Implementations of a method of wirebonding may include providing a bond wire; placing the bond wire adjacent to a surface of a substrate using a bond head; lifting the bond head away from the bond wire a predetermined distance, causing the bond wire to lift from the surface of the substrate; cutting the bond wire; and forming a first wirebond on the surface of the substrate using the bond head.

Implementations of a method of wirebonding may include one, all, or any of the following:

The method may include forming a tip adjacent to the first wirebond and orienting the tip at an angle away from a surface of the substrate through forming of a second wirebond.

The angle of the tip may be over 15 degrees.

Lifting the bond head away from the bond wire a predetermined distance may occur before cutting the bond wire.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side view of a first bond wire during a cutting process;

FIG. 2 is a side view of the first bond wire during a bonding process;

FIG. 3 is a side view of a second bond wire during a cutting process;

FIG. 4 is a side view of the second bond wire during a bonding process;

FIG. 5 is a side view of the first bond wire prior to a bonding process;

FIG. 6 is a side view of the second bond wire prior to a bonding process;

FIG. 7 is a perspective view of the tip of the first bond wire following the cutting process;

FIG. 8 is a perspective view of the tip of the second bond wire following the cutting process;

FIG. 9 is a perspective view of a plurality of wirebonds resulting from a first wirebonding process;

FIG. 10 is a perspective view of a plurality of wirebonds resulting from a second wirebonding process;

FIG. 11 is a side view of the first bond wire prior to a bonding process;

FIG. 12 is a backside view of the first bond wire prior to a bonding process;

FIG. 13 is a topside view of the first bond wire prior to a bonding process;

FIG. 14 is a side view of the second bond wire prior to a bonding process;

FIG. 15 is a backside view of the second bond wire prior to a bonding process;

FIG. 16 is a topside view of the second bond wire prior to a bonding process;

FIG. 17 is a perspective view of a photomicrograph of a wirebond formed using the first wirebonding process relative to a location of a polyimide layer; and

FIG. 18 is a perspective view of a photomicrograph of a wirebond formed using the second wirebonding process relative to a location of a polyimide layer.

### DESCRIPTION

This disclosure, its aspects and implementations, are not limited to the specific components, assembly procedures or method elements disclosed herein. Many additional components, assembly procedures and/or method elements known in the art consistent with the intended bond wires and methods of wirebonding will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such bond wires and methods of wirebonding, and implementing components and methods, consistent with the intended operation and methods.

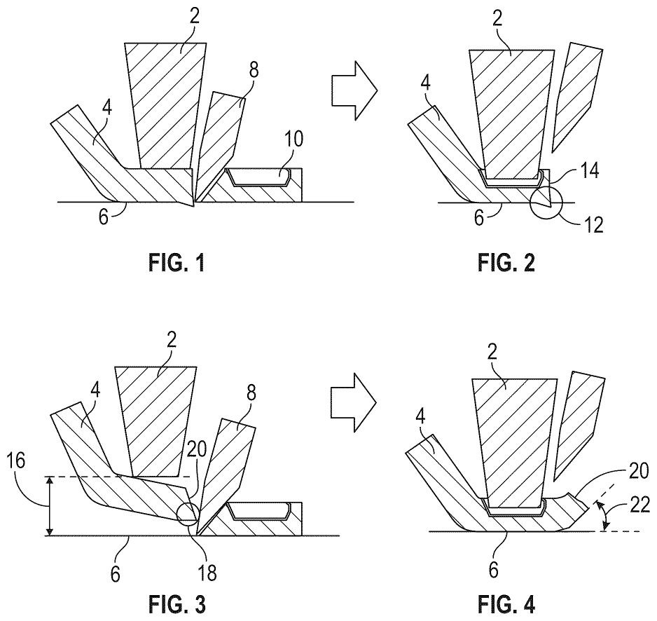

Referring to FIG. 1, during a particular wirebonding process, a bond tool 2 is used to hold a bond wire 4 against a surface 6 of a semiconductor die while cutter 8 presses down on the bond wire 4 and cuts through it, separating it from an existing wirebond 10 and allowing the bond wire 4 and bond tool 2 to move to the next location where a wirebond is needed. FIG. 2 illustrates the bond wire 4 following cutting during a bonding process carried out by the bond tool 2. As illustrated, burr 12 at the tip 14 of the bond wire 4 is pressed against the surface 6 of the semiconductor die during the bonding process.

It has been observed that damage to semiconductor die corresponding with the position of the burr 12 occurs under certain conditions. This damage can cause yield losses as the structures in the device layer under the burr/wirebond are broken or otherwise reduced in effectiveness as a result. In this document, various processes for wirebonding that creates a bond wire tip with a specific shape and a resulting wirebond with a specific shape are disclosed. In various process implementations, no changes to the structure of the wirebonding equipment itself (bond tool, cutter, etc.), are employed so that the process is implemented using an altered recipe/bonding program. The ability to implement the process without changing the structure of an existing wirebonder can greatly reduce the cost of the implementation of the process.

Referring to FIG. 3, the bond tool 2 is illustrated during a cutting process of bond wire 4 using cutter 8. In this side view, the bond wire 4 is lifted above the surface 6 of the semiconductor die 6 a predetermined distance 16 as the cutter 8 cuts through the thickness of the bond wire 4. In some implementations, the predetermined distance is greater than or equal to about 1.3 times the diameter of the bond wire. As illustrated, after the cutting is completed, the tip of the bond wire is lifted above the surface 6 of the semiconductor die and a flattened portion 18 is created adjacent to the tip 20. FIG. 4 illustrates the bond wire 4 during the subsequent bonding process using the bond tool 2 which show that the tip 20 bends upwardly away from the surface 6 at an angle 22 that causes the tip 20 to face away from the surface 6. By comparison with the drawing FIG. 2, there is no burr 12 that is pressed against the surface 6 during or after the wirebonding process is completed. As a result, it has been observed that there is no visible or functional damage to the active layer structures of the semiconductor die following wirebonding using this cutting and bonding process. In various implementations, the angle is over about 15 degrees. In other implementations, the angle is over about 25 degrees. In yet other implementations, the angle is over about 30 degrees.

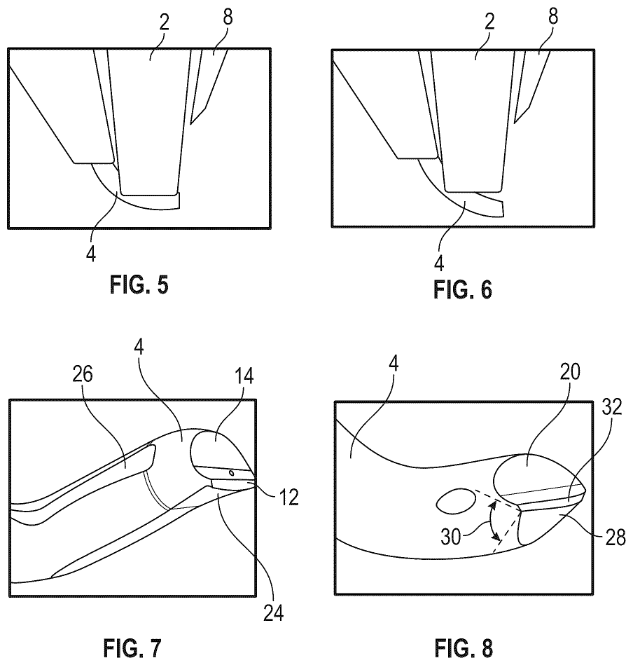

FIG. 5 illustrates the position of the bond wire 4 after the cutting process with cutter 8 is completed as the bond tool 2 is moving to the next wire bonding position when the wirebonding process of FIGS. 1 and 2 is being used. Because the bond tool 2 has been holding the bond wire 4 down against the surface 6 of the semiconductor die during cutting, the bond wire 4 has been physically conformed/deformed to correspond with the surface(s) of the bond tool 2. The shape of the tip 14 is illustrated in FIG. 7, where the presence of the burr 12 on one side of the face of the tip 14 along with a flattened portion 24 that results from the pressing down of the bond tool 2 on the surface (and marks 26 on each side of the bond wire 4 from the end of the bond tool 2) can be seen. Because the tip 14 of the bond wire 4 plastically deforms during the cutting process, bond wire material flows away from the face of the tip 14 as the cutter 8 passes through the thickness of the bond wire 4, creating the burr 12 on one side of the face.

In contrast, FIG. 6 illustrates how, when the cutting process of FIGS. 3-4 is used, the end of the bond wire 4 floats free of the bond tool 2 after cutting. The resulting shape of the tip 20 is illustrated in FIG. 8. Here, because the bond wire 4 is supported above the surface 6 of the semiconductor die during the cutting process, a side 28 of the tip 20 only contacts the surface briefly as the cutter 8 reaches through the thickness of the bond wire 4, causing just a small portion of that side to plastically deform and form a flat plane. This causes an angle 30 to be present in the face of the tip 20 where burr 32 is located in roughly the middle of the face of the tip 20. Because the end of the bond wire 4 is curved rather than being flattened, the resulting pressure of the bond tool 2 on the bond wire causes the face of the tip 20 and the burr 32 to rotate upwardly away from the surface 6, preventing contact (and in some implementations, any contact) between the burr 32 or the face of the tip 20 and the surface 6.

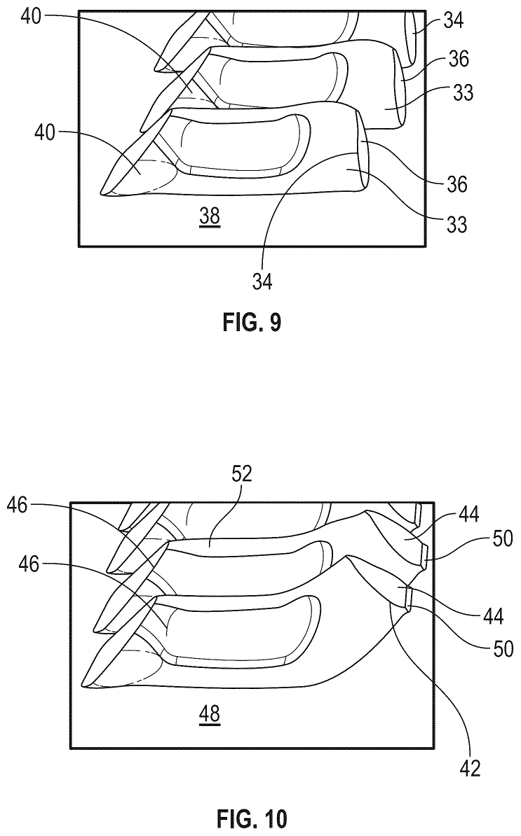

Referring to FIG. 9, a photomicrograph of a set of wirebonds 33 formed using the process of FIGS. 1-2 is illustrated. As illustrated, these wirebonds 33 have tips 34 with faces 36 that are oriented substantially perpendicularly to the surface 38 upon which they are bonded. The photomicrograph also indicates that the force of the bonding process has caused the burr son the side of the faces 36 to plastically deform back into the material of the bond wires 40 causing their shape to shift from their appearance in FIG. 7 to FIG. 9.

In contrast, referring to FIG. 10, the curve on the end of the bond wire observed in FIG. 8 causes the tip 42 and the face 44 of each of the wirebonds 46 to rotate upwardly away from the surface 48 during the wirebonding process. As a result, the burr 32 in FIG. 8 winds up being on the edge of the face 44, as shows in FIG. 10 as burr 50 due to the plastic deformation of the end of the bond wires 52 during the wirebonding process. It is clear by inspection that this burr 50 has not at any time contacted the surface 48 during the wirebonding process.

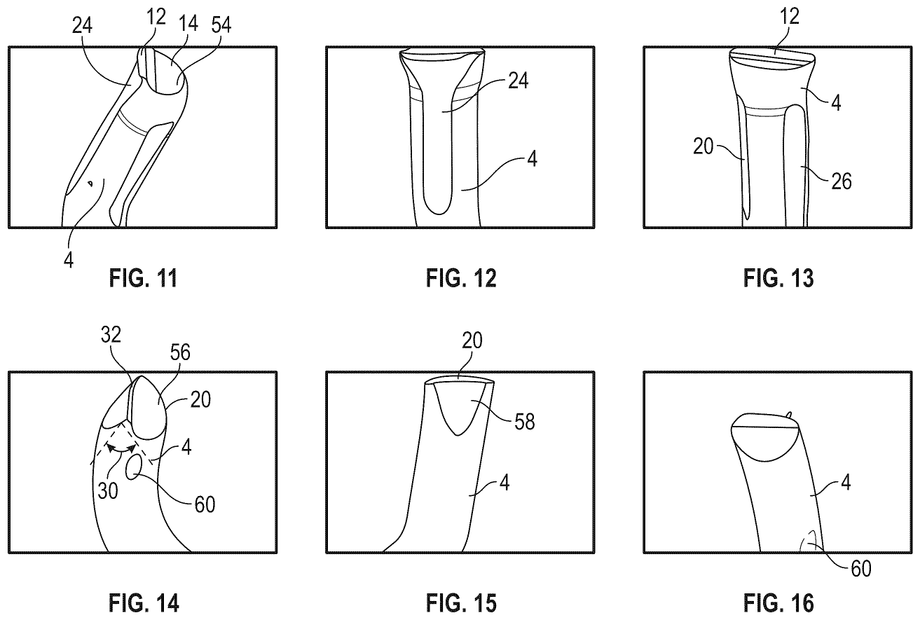

FIG. 11 is another side view (opposite side view of FIG. 7) of the tip 14 of the bond wire 4 which also shows the position of the burr 12 on the edge of the face 54 of the tip 14. It also shows the flattened portion 24 along one side of the bond wire 4 caused by the pressure of the bond tool during the cutting process. The extent of the flattened portion 24 along the length of the bond wire 4 is visible in the backside view of the bond wire 4 in FIG. 12. The deformation of the bond wire 4 on the topside of the bond wire 4 is visible with the extent of the marks 26 on either side of the bond wire 4. The net result of the flattening of the backside of the bond wire 4 and the creation of the deformation forming the marks 26 on the bond wire is that the overall cross section of the bond wire becomes less circular and more flattened with the widest portion aligned with the position of the burr 12. This overall flattening of the bond wire 4 during the cutting process may help accentuate the shape of the burr 12, causing it to become more pronounced. As the burr 12 becomes more pronounced, it can cause more damage to the surface of the semiconductor die as the burr 12 is pressed against that surface during the subsequent wirebonding process. Thus the combined effects of the pressure applied by the bonding tool during the cutting process can make the resulting burr more destructive to the semiconductor die.

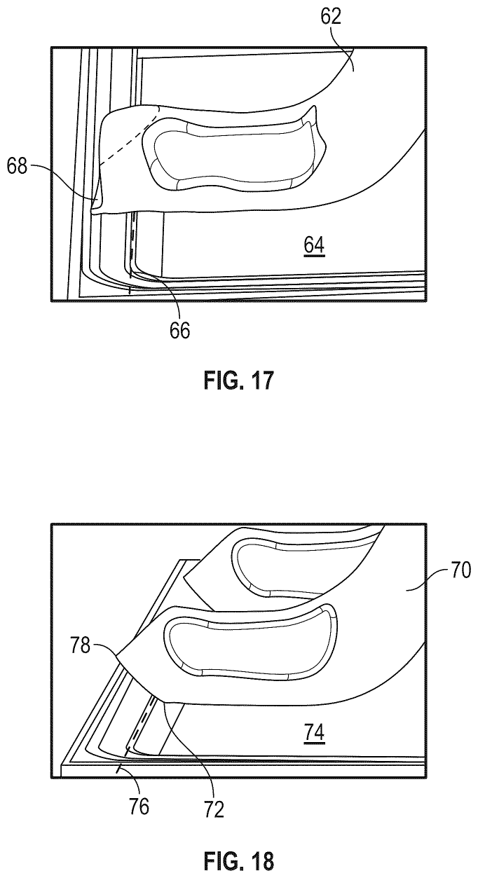

In contrast, the appearance of the bond wire 4 from FIG. 8 following the cutting process of FIGS. 3-4, is that it retains most of its original elliptical cross sectional shape. In this side view (the opposite side view from that of FIG. 8), the presence of the burr 32 substantially in the middle of the face 56 of the tip 20 forming angle 30 is visible. The small amount of flattening deformation caused by the brief contact of the tip 20 of the bond wire 4 on the surface during the cutting action is visible in the backside view of FIG. 15 in flattened portion 58. The topside view in FIG. 16 shows that, unlike the bond wire 4 in FIGS. 11 and 13, the bond wire has minimal marks 60 resulting from pressure from the bond tool itself, which help preserve the overall elliptical shape of the bond wire 4. Since the burr 32 is placed near center of the face 56 of the tip 20, it is unlikely that the burr 32 will contact the surface of the semiconductor device during the wirebonding process.

While references in this document to the wirebonding surface have been to semiconductor devices thus far in this document, these references also apply equally to other wirebonding surfaces (leadframes, substrates, interposers, etc.) as the wirebonding process is not surface-specific. However, the surface damage that has been leading to yield loss has been observed where the surface is a semiconductor device surface.

The ability to prevent the burr 12 from contacting the wirebonding surface may also create additional benefits beyond preventing damage at the burr location to the active layer(s) of the semiconductor device. Referring to FIG. 17, an implementation of a wirebond 62 created using the process of FIGS. 1-2 is illustrated. Here the wirebond 62 has been bonded to a pad 64 that has been surrounded by a layer of polyimide intended to protect the edges of the layer(s) from which the pad 64 is made. The layer of polyimide is not visible in this view because FIG. 17 is a photomicrograph created using scanning electron microscopy, which required that the layer of polyimide be removed via etching in order for the electrons to resolve the surfaces shown in the image. The location of the original edge of the layer of polyimide, however, is illustrated by dotted line 66. Here, the burr 68 of the wirebond 62 is located past dotted line 66, meaning that the burr 68 rested on the layer of polyimide before the layer was removed. Because polyimide is a polymer material, the mechanical stress of the impact of the burr 68 can cause cracking, delamination, or other damage to the layer of polyimide during the bonding process. As the layer of polyimide is damaged, the layer(s) of the pad 64 can also be correspondingly damaged or left unprotected because of the polyimide damage. As a result, the strength of the wirebond 62 can suffer and/or corrosion or moisture can penetrate into the layers/wirebond due to the lack of protection from the layer of polyimide.

Somewhat surprisingly, as illustrated in FIG. 18, the use of the process of FIGS. 3-4 causes the edge 72 of the wirebond 70 that contacts the pad 74 to be placed inside the edge of the layer of polyimide indicated by dotted line 76. As with FIG. 17, since the photomicrograph of FIG. 18 is also a scanning electron micrograph, the layer of polyimide has been removed prior to imaging. Since the burr 78 is angled up and away from the pad 74, the burr (and the face 80) of the wirebond 70 never contacted the pad 74 or the layer of polyimide during the wirebonding process. Because of this, no damage to the layer of polyimide due to the wirebonding process would be expected, and any of the previously mentioned issues that could occur due to such damage can be prevented.

The cutting process and wirebonding process disclosed herein may be used with a wide variety of bond wire types, including coated bond wires, or bond wires that do not include any other material added to the exterior of the bond wires (uncoated). The bond wire may include a wide variety of electrically conductive materials including, by non-limiting example, copper, copper alloys, aluminum, aluminum alloys, gold, gold alloys, silver, silver alloys, nickel, nickel alloys, any combination thereof, or any other wirebondable electrically conductive material. Where the bond wire is a coated bond wire, the coating may be formed by one or more layers of any of a wide variety of electrically conductive materials including, by non-limiting example, nickel, nickel alloys, aluminum, aluminum alloys, gold, gold alloys, tin, tin alloys, lead, lead alloys, palladium, palladium alloys, copper, copper alloys, silver, silver alloys, platinum, platinum alloys, any combination thereof, or any other electrically conductive material. The particular size (diameter, etc.) of the bond wires may be selected depending on the characteristics of the wirebond and electrical connection desired (larger diameters for higher currents, etc.).

The wirebonding processes and bond wires/wirebonds disclosed herein can be used to form electrical interconnects in any semiconductor package that employs wirebonds. Thes can include various semiconductor packages that include one or more substrates as a component of the semiconductor packages. The substrates can be formed using various materials and may be, by non-limiting example, direct bonded copper (DBC) substrates, active metal brazed (AMB) substrates, aluminum nitride substrates, alumina substrates, insulated metal substrates (IMS), leadframes, any combination thereof, or any other substrate type. One or more semiconductor die may be coupled to the substrates (semiconductor substrates) which may be formed of various semiconductor materials including, by non-limiting example, silicon, silicon carbide, silicon on insulator, gallium nitride, gallium arsenide, ruby, sapphire, wide band gap materials, or any other semiconductor substrate type. A wide variety of semiconductor die including various semiconductor device types may be included in the various semiconductor package implementations disclosed herein including, by non-limiting example, power semiconductor devices, diodes, metal oxide field effect transistors (MOSFETs), insulated gate bipolar transistors (IGBTs), high electron mobility transistors (HEMTs), processors, microprocessors, memory, rectifiers, hybrid devices, image sensor devices, or any other semiconductor device type.

In various package implementations, the substrates may include one or more traces in one or more layers thereon. In various implementations, the substrates may include a combination of one or more electrically conductive layers with one or more electrically insulative layers. In some substrate implementations, a top layer of the substrate is exposed after package formation; in others, a mold compound or potting compound may cover the top layer. For packages where a mold compound is employed with the substrate, the mold compound may cover various surfaces of the substrate to help form electrically insulated areas. In various package implementations, various electrical connectors may be employed to form electrical connections between to the substrate and the one or more semiconductor die included therein including, by non-limiting example, wire bonds, clips, leads, pins, or any other electrical connector type.

In various semiconductor package implementations, the package may include a combination of a substrate with another substrate or with a leadframe in order to form the desired mechanical/electrical configuration. Where the semiconductor package includes a leadframe attached to a substrate using a solder material, the solder may first be applied to the substrate and then the leadframe may be held against/supported on the substrate during a reflow operation using a reflow oven/system that melts the solder and forms a permanent joint between the leadframe and the substrate.

In various implementations, the semiconductor package may be an image sensor package that includes one or more image sensor die thereon. The image sensor package may be a stacked die package where memory, a digital signal processor, a processor, a microprocessor, or another controller are bonded to an image sensor semiconductor die. The bonding may be hybrid bonding, oxide bonding, metal bonding, or bonding using an adhesive, glue, or other bonding material. Through silicon/through oxide vias may also be employed. The various components of the image sensor package may include one or more wirebonds and bond wires like those disclosed herein.

In places where the description above refers to particular implementations of bond wires and methods of wirebonding and implementing components, sub-components, methods and sub-methods, it should be readily apparent that a number of modifications may be made without departing from the spirit thereof and that these implementations, implementing components, sub-components, methods and sub-methods may be applied to other bond wires and methods of wirebonding.

1-6. (canceled)

7. A method of wirebonding comprising:
providing a bond wire;
forming a first wirebond on a surface of a substrate using a bond head;
lifting the bond head away from the bond wire a predetermined distance, causing the bond wire to lift from the surface of the substrate;
cutting the bond wire; and
forming a second wirebond on the surface of the substrate using the bond head.

8. The method of claim 7, further comprising forming a tip adjacent to the first wirebond and orienting the tip at an angle away from a surface of the substrate through the forming of the second wirebond.

9. The method of claim 8, wherein the angle of the tip is over 15 degrees.

10. The method of claim 8, wherein the angle of the tip is over 25 degrees.

11. The method of claim 8, wherein the angle of the tip is over 30 degrees.

12. The method of claim 7, further comprising forming a tip adjacent to the first wirebond and wherein a cut face of the tip faces away from the surface.

13. The method of claim 12, further comprising forming a burr in a cut face of the tip substantially centered in the cut face.

14. The method of claim 12, further comprising forming a burr at an angle to a cut face of the tip.

15. The method of claim 7, wherein the predetermined distance is 1.3 times a diameter of the bond wire.

16. The method of claim 7, wherein lifting the bond head away from the bond wire a predetermined distance occurs before cutting the bond wire.

17. A method of wirebonding comprising:
providing a bond wire;
placing the bond wire adjacent to a surface of a substrate using a bond head;
lifting the bond head away from the bond wire a predetermined distance, causing the bond wire to lift from the surface of the substrate;
cutting the bond wire; and
forming a first wirebond on the surface of the substrate using the bond head.

18. The method of claim 17, further comprising forming a tip adjacent to the first wirebond and orienting the tip at an angle away from a surface of the substrate through forming of a second wirebond.

19. The method of claim 18, wherein the angle of the tip is over 15 degrees.

20. The method of claim 17, wherein lifting the bond head away from the bond wire a predetermined distance occurs before cutting the bond wire.
